(19) United States
(12) Patent Application Publication
(10) Pub. No.: US 2025/0246242 A1
(43) Pub. Date: Jul. 31, 2025

(54) NON-VOLATILE MEMORY DEVICE WITH VARIABLE BIT LINE CAPACITANCE AND PROGRAM METHOD THEREOF

(71) Applicant: SAMSUNG ELECTRONICS CO., LTD., Suwon-si (KR)

(72) Inventors: Ki-Ryun KWON, Suwon-si (KR); Se-Heon BAEK, Suwon-si (KR)

(73) Assignee: SAMSUNG ELECTRONICS CO., LTD., Suwon-si (KR)

(21) Appl. No.: 19/022,713

(22) Filed: Jan. 15, 2025

(30) Foreign Application Priority Data
Jan. 26, 2024 (KR) 10-2024-0012047

(51) Int. Cl. G11C 16/10; G11C 16/04; G11C 16/08; G11C 16/24

(52) U.S. Cl. CPC G11C 16/102; G11C 16/0483; G11C 16/08; G11C 16/24

(57) ABSTRACT

A non-volatile memory device includes a first memory block connected to bit lines; a second memory block connected to the bit lines and including string selection lines, word lines, and cell strings connected to the string selection lines and the word lines; a row decoder configured to provide a turn-on voltage to at least one of the string selection lines of the second memory block during a program operation of the first memory block; and a page buffer configured to perform program or inhibit settings for the bit lines during the program operation.

### CROSS-REFERENCE TO RELATED APPLICATIONS

This application claims priority under 35 U.S.C. § 119 to Korean Patent Application No. 10-2024-0012047, filed on Jan. 26, 2024, in the Korean Intellectual Property Office, the disclosure of which is incorporated by reference herein in its entirety.

### BACKGROUND

### 1. Field

Embodiments of the present disclosure relate to a semiconductor memory device, and more specifically, to a non-volatile memory device with variable bit line capacitance and a method of programming the same.

### 2. Brief Description of Background Art

Semiconductor memory devices can be broadly divided into volatile memory and non-volatile memory. Volatile memory (e.g., dynamic random-access memory (DRAM) or static random-access memory (SRAM)) has fast reading and writing speeds, but stored data is lost when power supply is cut off. On the other hand, non-volatile memory can retain stored data even if the power supply is cut off.

Flash memory devices, a type of non-volatile memory, program memory cells to have a specific threshold voltage to store data. In other words, through the programming of the memory cell, electrons are trapped in a nitride film that makes up the memory cell. The threshold voltage level of a memory cell is determined depending on the amount of electrons trapped in the nitride film. For programming memory cells, bias is provided through bit lines, word lines, string selection lines, etc., during program operation.

As the generation transition of flash memory devices progresses, capacitance of one memory block is rapidly increasing. This is accompanied by a reduction in the bit line length for configuring one block. Ultimately, a decrease in the capacitance of a bit line composed of metal lines is inevitable. A reduction in the capacitance of the bit line leads to a deterioration in the distribution of the threshold voltage and a decrease in program efficiency, which ultimately leads to a decrease in program performance. Therefore, there is a need for a bit line capacitance control method that will stabilize bit line voltage during program operation.

### SUMMARY

Embodiments of the present disclosure provides a non-volatile memory device with variable bit line capacitance and a programming method thereof that overcomes a decrease in program efficiency that occurs as the size of a bit line is reduced.

According to embodiments of the present disclosure, a non-volatile memory device is provided and includes: a first memory block connected to bit lines; a second memory block connected to the bit lines and including string selection lines, word lines, and cell strings connected to the string selection lines and the word lines; a row decoder configured to provide a turn-on voltage to at least one of the string selection lines of the second memory block during a program operation of the first memory block; and a page buffer configured to perform program or inhibit settings for the bit lines during the program operation.

According to embodiments of the present disclosure, a method of programming a non-volatile memory device is provided and includes: setting bit lines of a first memory block that includes target memory cells to be programmed; setting at least one string selection line of a second memory block connected to the bit lines to a turn-on voltage; and applying a program voltage to word lines of the target memory cells of the first memory block.

According to embodiments of the present disclosure, a non-volatile memory device is provided and includes: a first memory block connected to at least one bit line; and a second memory block configured to connect at least one cell string to the at least one bit line in response to a turn-on voltage applied to string selection lines during a program operation of the first memory block.

### BRIEF DESCRIPTION OF DRAWINGS

The above and other aspects of embodiments of the present disclosure will become apparent by describing in detail non-limiting example embodiments of the present disclosure with reference to the accompanying drawings, including:

FIG. 1 is a block diagram illustrating a non-volatile memory device according to an embodiment of the present disclosure.

FIG. 2 is a diagram illustrating a structure of a dummy block shown in FIG. 1.

FIG. 3 is a diagram showing a string structure of a dummy block and a selected block sharing a bit line.

FIG. 4 is a circuit diagram showing a cell string structure of the selected block and dummy block of FIG. 3.

FIG. 5 is a circuit diagram illustrating a change in bit line capacitance of a dummy block provided through control of a string selection line.

FIG. 6 is a diagram illustrating a program state of memory cells of a dummy block.

FIG. 7 is a block diagram showing a function of a row decoder of embodiments of the present disclosure.

FIG. 8 is a timing diagram showing a control method for an operation mode of cell strings of a dummy block of an embodiment of the present disclosure.

FIG. 9 is a timing diagram showing a control method for an operation mode of cell strings of a dummy block of an embodiment of the present disclosure.

FIG. 10 is a diagram showing a number of strings of the dummy block contributing to addition of bit line capacitance for each program loop under conditions of FIG. 9.

FIG. 11 is a flowchart showing a programming method according to an embodiment of the present disclosure.

FIG. 12 is a block diagram showing a storage system including a non-volatile memory device of an embodiment of the present disclosure.

### DETAILED DESCRIPTION

It is to be understood that both the foregoing general description and the following detailed description describe non-limiting example embodiments of the present disclosure. The same reference numbers may be used in the description and drawings to refer to the same or like parts.

It will be understood that when an element is referred to as being “on,” “connected to,” or “coupled to” another element, it can be directly on, connected to, or coupled to the other element or intervening elements may be present. In contrast, when an element is referred to as being “directly on,” “directly connected to,” or “directly coupled to” another element, there are no intervening elements.

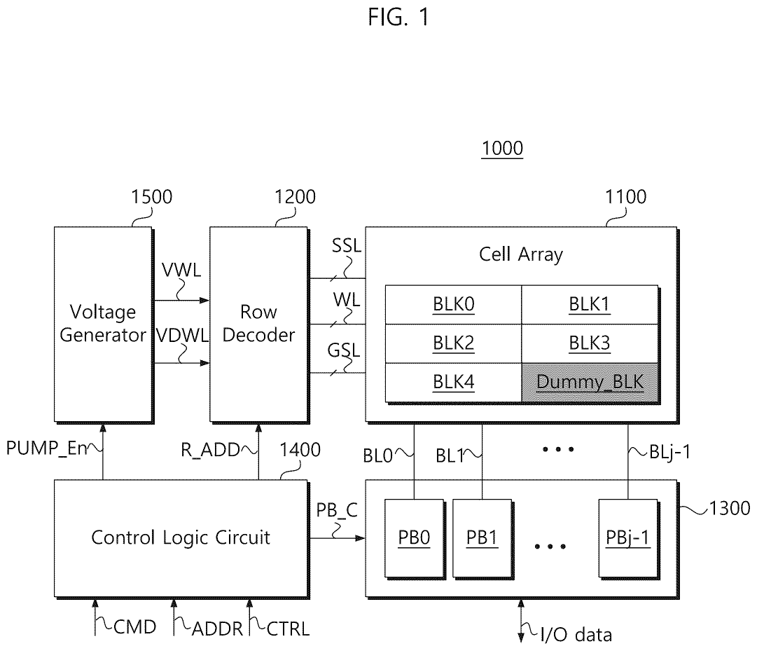

FIG. 1 is a block diagram illustrating a non-volatile memory device according to an embodiment of the present disclosure. Referring to FIG. 1, the nonvolatile memory device 1000 may include a cell array 1100, a row decoder 1200, a page buffer circuit 1300, a control logic circuit 1400, and a voltage generator 1500.

The cell array 1100 may include a plurality of memory blocks (e.g., memory blocks BLK0, BLK1, BLK2, BLK3, BLK4, and a dummy block Dummy_BLK). Each of the plurality of memory blocks may have a vertical three-dimensional structure. Each memory block may comprise or consist of a plurality of pages. Each page may be composed of a plurality of memory cells. Multi-bit data can be stored in each memory cell. Each memory block may be an erase unit, and each page can be a read or write unit.

The cell array 1100 may be formed in a direction perpendicular to a substrate. Gate electrode layers and insulation layers may be deposited alternately on the substrate. Each memory block may be connected to the row decoder 1200 through a string selection line SSL, a plurality of word lines, and a ground selection line GSL. A number of stacked gate electrode films on which the word lines of the cell array 1100 are formed increases as product generations advance.

As the density of memory cells increases, the relative length of the bit lines decreases. As the length of the bit line decreases, the capacitance of the bit line required to maintain the setup voltage during program operation tends to decrease. During program operation, generally, after setup of the bit line, the bit line is blocked from a sensing node of the page buffer circuit 1300. In this state, when a program voltage is applied to the word line, the bit line set to the program bit line voltage (e.g., 0V) may be boosted due to insufficient capacitance of the bit line. If the bit line voltage is boosted to the inhibit level, memory cells to be programmed may be program inhibited.

The cell array 1100 of embodiments of the present disclosure may include a dummy block Dummy_BLK that is activated in addition to the selected memory block during a program operation to compensate for the capacitance of the bit line. The dummy block Dummy_BLK may have a structure that provides additional bit line capacitance of the memory block selected for the program. The dummy block Dummy_BLK may have substantially the same structure as the memory blocks BLK0, BLK1, BLK2, BLK3, and BLK4 capable of writing and reading data. And the dummy block Dummy_BLK may have a structure that can select memory cells or strings through a string selection line SSL, a word line WL, and a ground selection line GSL. The dummy block Dummy_BLK of embodiments of the present disclosure may be differentiated from a dummy block that cannot store or control data in the general sense.

When the dummy block Dummy_BLK is activated, at least one string selection line SSL connected to the same bit line as the selected memory block may be activated. The number of NAND cell strings connected to the bit line can be controlled using the string selection line SSL of the dummy block Dummy_BLK. Additionally, the bit line capacitance of the selected memory block can be variably controlled according to the number of NAND cell strings. These features will be described in more detail below, with reference to the drawings.

The row decoder 1200 may select a word line of the cell array 1100 in response to a row address R_ADD. The row decoder 1200 provides a word line voltage VWL provided from the voltage generator 1500 to the select lines (e.g., the string selection line SSL, the ground selection line GSL) and word line WL of the memory block selected in the cell array 1100. The row decoder 1200 can select the word line during a program or read operation. The row decoder 1200 may provide a program voltage or a read voltage to the selected word line.

In particular, the row decoder 1200 may select cell strings of a dummy block Dummy_BLK with a shared bit line during a program operation for a selected memory block (e.g., memory block BLK0). The bit line capacitance of the selected memory block (e.g., memory block BLK0) may be increased by the increased capacitance provided by the cell strings of the dummy block Dummy_BLK. As the bit line capacitance increases, the boosting phenomenon of the bit line set to the program bit line voltage during program operation can be minimized. In addition, the row decoder 1200 may provide a dummy word line voltage VDWL to the word lines of the dummy block Dummy_BLK. The dummy word line voltage VDWL refers to a voltage capable of maintaining the memory cells of the dummy block Dummy_BLK in a turned-off state.

The row decoder 1200 may vary the number of cell strings selected in the dummy block Dummy_BLK according to the number of program loops. In other words, the largest bit line capacitance may be required in the first program loop where programming and verification for the lowest program state (e.g., state P1) are performed. At this time, the maximum number of cell strings can be selected in the dummy block Dummy_BLK to add the largest bit line capacitance. Here, selecting a cell string means that the bit line and the cell string are connected.

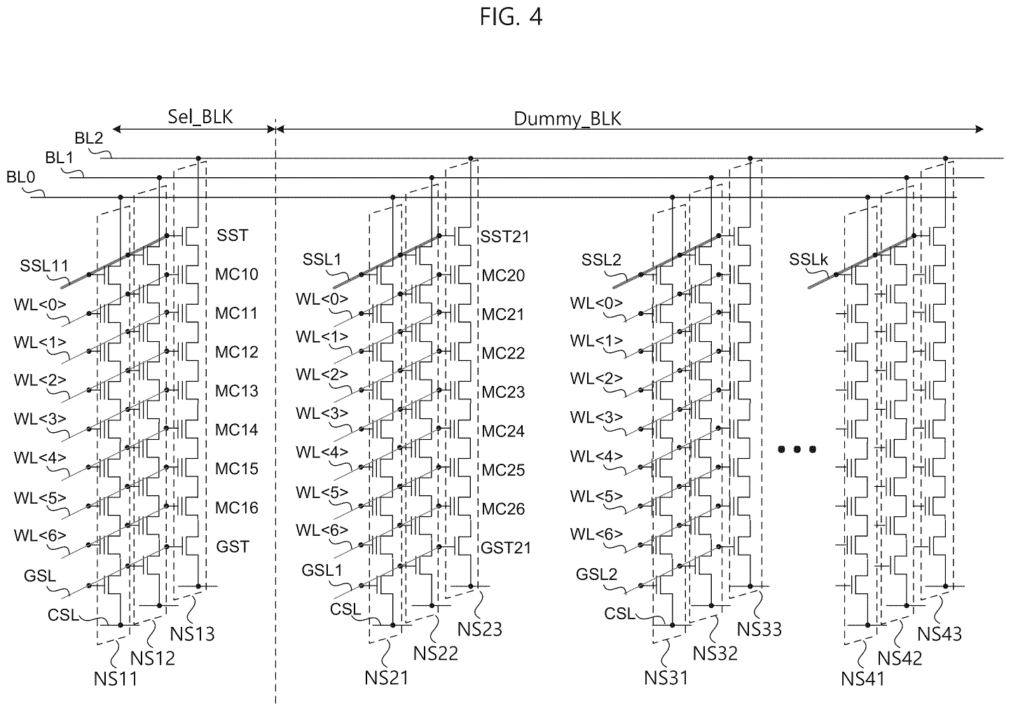

Thereafter, the row decoder 1200 may reduce the number of cell strings selected in the dummy block Dummy_BLK as the number of program loops increases. Additionally, the row decoder 1200 may stop selecting cell strings of the dummy block Dummy_BLK after program success for a specific program state (e.g., state P3). Here, in order to select the cell string of the dummy block Dummy_BLK, a string selection transistor SST connecting the corresponding cell string and the bit line must be turned on. The gate of the string selection transistor (e.g. string selection transistor SST of FIG. 4) is connected to the string selection line SSL. Accordingly, the bit line and the cell string can be connected through control of the string selection line SSL.

The page buffer circuit 1300 may be connected to the cell array 1100 through bit lines (e.g., bit lines BL0 to BLj-1, wherein j is a positive integer). The page buffer circuit 1300 may precharge or sense the bit lines BL0 to BLj-1 connected to the memory cells in response to a page buffer control signal PB_C provided from the control logic circuit 1400. The page buffer circuit 1300 may include a plurality of page buffers (e.g., page buffers PB0 to PBj-1). A plurality of page buffers (e.g., the page buffers PB0 to PBj-1) may be respectively connected to memory cells through a plurality of bit lines (e.g., the bit lines BL0 to BLj-1). The page buffer circuit 1300 may operate as a write driver or a sense amplifier according to the operation mode.

For a program operation, the page buffer circuit 1300 may apply a bit line voltage corresponding to data to be programmed to a selected bit line. During a bit line setup operation for programming, a program bit line voltage (e.g., 0V) is applied to the bit line connected to the cell to be programmed in the target state. On the other hand, an inhibited bit line voltage (e.g., 2V) is applied to the bit line connected to the memory cell that is program inhibited. After bit line setup, the bit line is disconnected from the sensing node of the page buffer circuit 1300. This is because, in order to hide a data dump operation between latches within the page buffer circuit 1300, the bit line will be maintained charged to the setup level. Therefore, when the capacitance of the bit line charged with the program bit line voltage (e.g., 0V) is insufficient, a phenomenon in which the bit line voltage is boosted due to coupling during the program execution section may occur. In this case, memory cells to be programmed can be program inhibited.

The control logic circuit 1400 can control various operations within the nonvolatile memory device 1000 according to the mode. The control logic circuit 1400 may perform program, read, erase, etc,. operations on the cell array 1100 in response to the control signal CTRL, command CMD, and/or address ADDR. For example, the control logic circuit 1400 may generate a pump enable signal PUMP_En and a page buffer control signal PB_C for a program operation. The control logic circuit 1400 provides the pump enable signal PUMP_En to the voltage generator 1500, thereby controlling the voltage generator 1500 to generate the voltage required for read, write, and erase operations.

The control logic circuit 1400 may control the row decoder 1200 to adjust the number of cell strings selected in the dummy block Dummy_BLK for each loop during the program operation. That is, the control logic circuit 1400 controls the row decoder 1200 to vary the selection number of the string selection line SSL of the dummy block Dummy_BLK according to the number of program loops. Through this operation, the number of cell strings in the dummy block Dummy_BLK, which contributes to increasing bit line capacitance, can be optimized. Ultimately, as the number of loops increases under the control of the control logic circuit 1400, the size of the bit line capacitance compensated may gradually decrease. In addition, the control logic circuit 1400 controls the number of string selection lines SSL selected in the dummy block Dummy_BLK to be ‘0’ after a specific program loop, thereby preventing addition of bit line capacitance by the dummy block Dummy_BLK to be disabled.

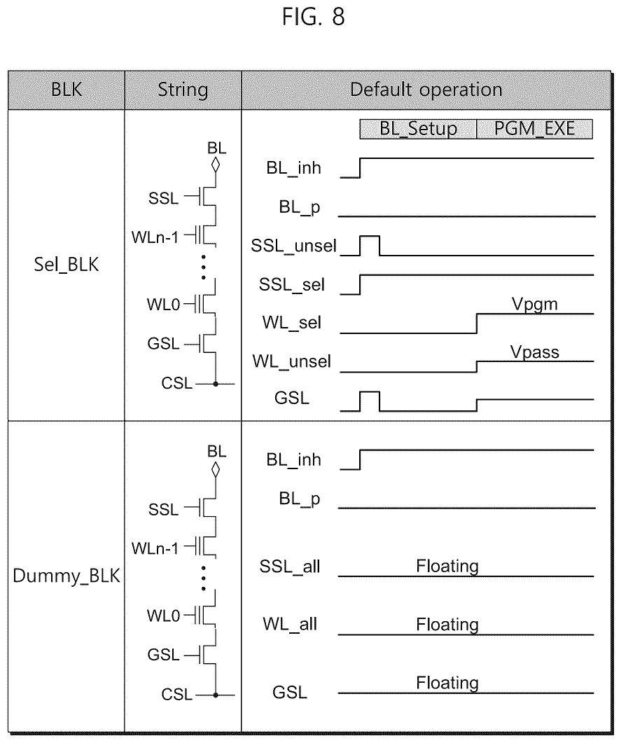

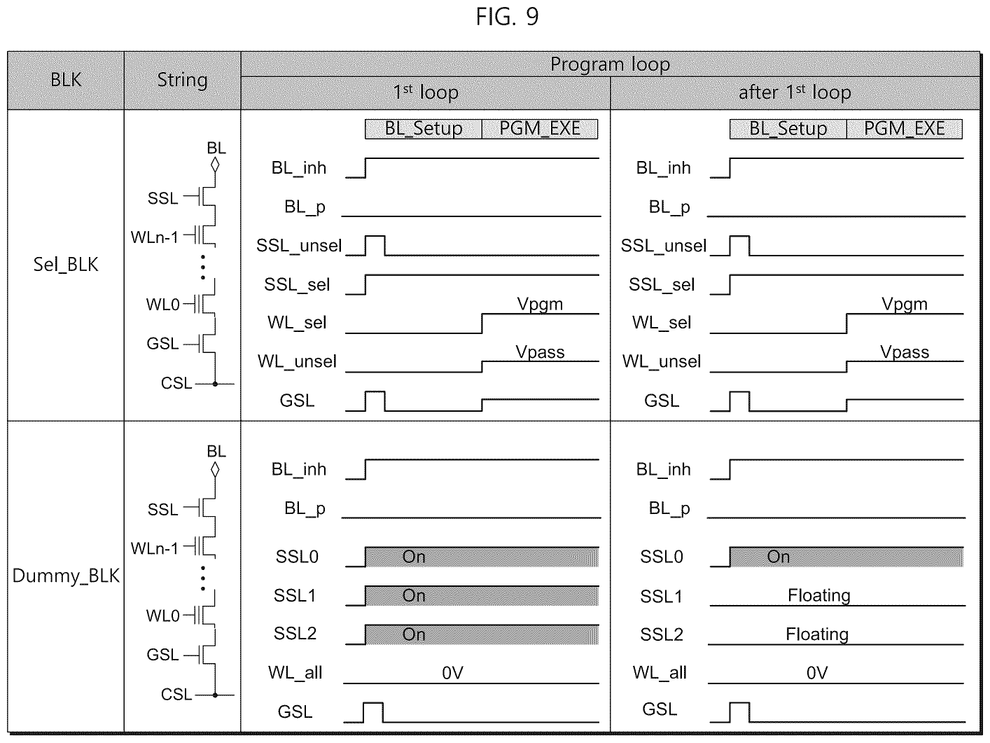

The voltage generator 1500 may generate a word line voltage VWL to read or write data in response to the pump enable signal PUMP_En from the control logic circuit 1400. The word line voltage VWL may be provided to a selected word line WL_sel or an unselected word line WL_unsel through the row decoder 1200 (see FIGS. 8-9). Generally, during a program operation, a program voltage Vpgm will be applied to the selected word line WL_sel and a pass voltage Vpass will be applied to the unselected word line uWL (see

FIGS. 8-9). However, it will be well understood that the word line voltage VWL is not limited to the voltage applied during a program operation, and may further include voltages of various levels. Additionally, the voltage generator 1500 may generate a dummy word line voltage VDWL. The dummy word line voltage VDWL corresponds to a word line voltage that can guarantee the turn-off state of memory cells included in the dummy block Dummy_BLK. The voltage generator 1500 may include a charge pump and a word line voltage generator for this purpose.

In the above, according to the nonvolatile memory device 1000 of embodiments of the present disclosure, the dummy block Dummy_BLK may be activated to compensate for the bit line capacitance during the program operation. The bit line capacitance of the selected memory block can be optimized by varying the number of activated string selection lines SSL of the dummy block Dummy_BLK. Program efficiency and program performance can be improved through compensation of bit line capacitance.

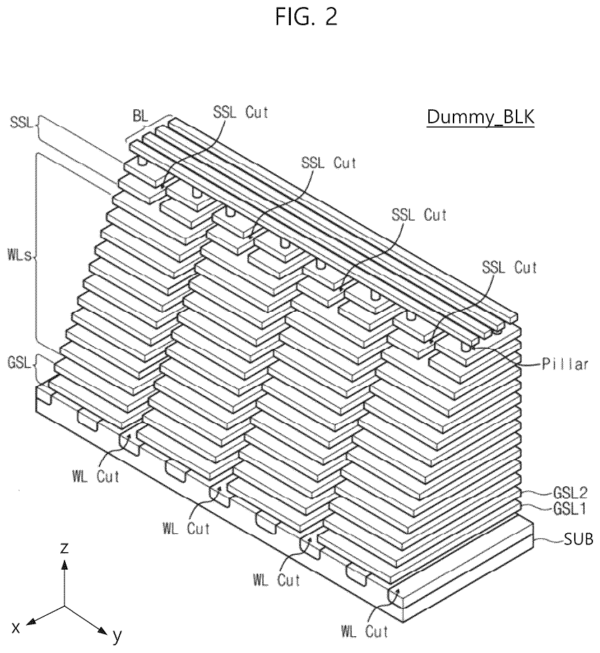

FIG. 2 is a diagram illustrating the structure of the dummy block Dummy_BLK shown in FIG. 1. Referring to FIG. 2, conductive layers and insulating layers may be alternately stacked on the substrate SUB to form a dummy block Dummy_BLK.

The dummy block Dummy_BLK may be formed by stacking at least a ground selection line GSL, a plurality of word lines WL, and at least one string selection line SSL in a plate shape between word line cuts (“WL Cut”) on a substrate. Here, at least one string selection line SSL is shown as being separated by a string selection line cut (“SSL Cut”). However, it will be understood that this structure is a non-limiting example.

Additionally, each word line cut (“WL Cut”) may include a common source line CSL (see FIGS. 4 and 8-9). For example, the common source line CSL included in each word line cut (“WL Cut”) may be connected in common. A pillar connected to the bit line BL penetrates at least one ground selection line GSL, a plurality of word lines WL, and at least one string selection line SSL in the z-direction, so that the NAND cell string may be formed.

Here, the bit lines BL are formed extending in the y-direction, and are connected to adjacent memory blocks in the y-direction. Memory blocks BLK0, BLK1, BLK2, BLK3, BLK4 (see FIG. 1) into which data is written or read may also be formed to have substantially the same structure as the structure of the dummy block Dummy_BLK.

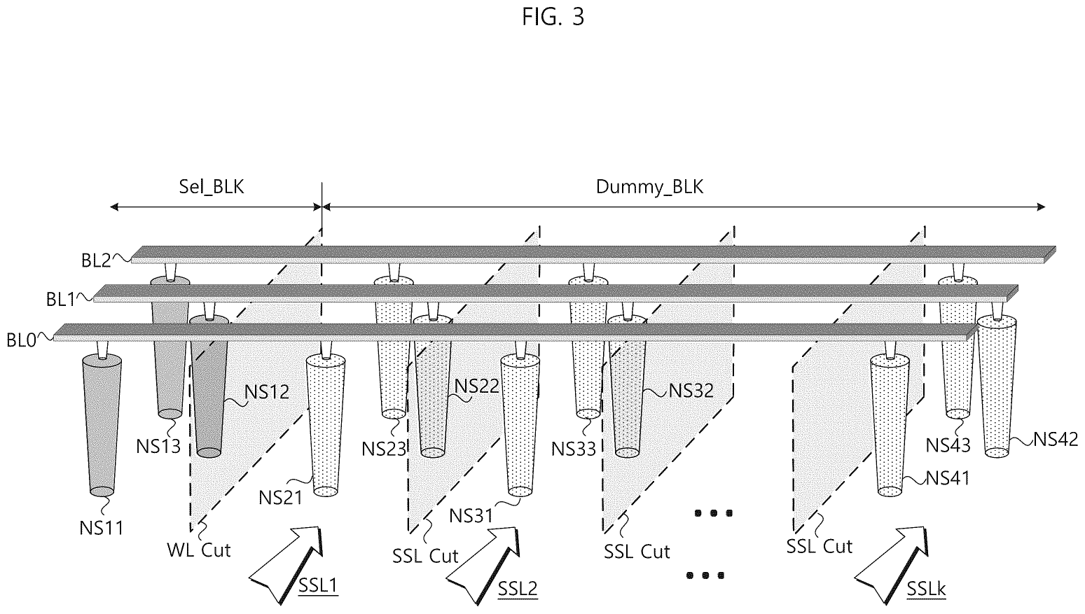

FIG. 3 is a diagram showing the string structure of a dummy block and a selected block sharing a bit line. Referring to FIG. 3, the bit line capacitance of the selected block Sel_BLK can be adjusted through driving the string selection line SSL of the dummy block Dummy_BLK. Here, the selected block Sel_BLK may be one of the memory blocks BLK0, BLK1, BLK2, BLK3, and BLK4 of FIG. 1.

When the program for the selected block Sel_BLK starts, setup for the bit lines BL0 to BL2 is performed. In other words, each of the bit lines BL0 to BL2 is charged with the program bit line voltage (e.g., 0V) or the inhibit bit line voltage (e.g., VDD). When the bit line setup is completed, the bit lines BL0 to BL2 are blocked from the sensing node of the page buffer circuit 1300, and program execution begins in which the program voltage Vpgm is applied to the word lines. However, since bit line forcing does not need to be applied in the first program loop, the bit line remains blocked from the sensing node during the program execution section. On the other hand, in the second or higher program loop, a bit line forcing voltage to prevent overprogramming may be applied to the corresponding bit line.

After bit line setup, the bit lines BL0 to BL2 must maintain the set voltage state while electrically disconnected (floating) from the sensing node of the page buffer circuit 1300. However, when the program voltage is applied to the word line during the program execution section, if the capacitance of the bit lines BL0 to BL2 is insufficient, the bit lines set up with the program bit line voltage (e.g., 0V) can be boosted by coupling. In this case, the program of the selected memory cells may be inhibited.

According to embodiment of the present disclosure, during the program operation of the selected block Sel_BLK, insufficient bit line capacitance can be compensated for by connecting the cell strings (e.g., cell strings NS21, NS22, NS23, . . . , NS43) of the dummy block Dummy_BLK to the bit lines BL0 to BL2. In addition, the compensated capacitance can be controlled step by step by varying the number of cell strings of the dummy block Dummy_BLK connected to the bit lines BL0 to BL2 according to the number of program loops of the selected block Sel_BLK.

To this end, in the first program loop during the program operation, the turn- on voltage can be applied to a set maximum number of string selection lines SSLs of the dummy block Dummy_BLK. And in the subsequent loop, the dummy block Dummy_BLK can be controlled by gradually reducing the number of string selection lines SSLs to which the turn-on voltage is applied. In other words, as shown, in the first program loop, the turn-on voltage is applied to all of the string selection lines SSL0 to SSLk, and in subsequent loops, the number of string selection lines SSL to which the turn-on voltage is applied may gradually decrease. At this time, the dummy word line voltage VDWL is provided to the word line of the dummy block Dummy_BLK. The dummy word line voltage VDWL may be provided as an off-cell voltage of memory cells in order for each cell string to provide maximum capacitance. In other words, in order to form maximum capacitance between channels formed by word lines and pillars, memory cells performing dielectric functions must be kept in an off state. Accordingly, the memory cells of the dummy block Dummy_BLK may be maintained in an erase state and 0V may be provided to the word line. However, embodiments of the present disclosure are not limited to the examples described herein. The dummy word line voltage VDWL provided to the dummy block Dummy_BLK may be defined as a level at which the memory cells of the selected cell string are maintained in an off state.

FIG. 4 is a circuit diagram showing the cell string structure of the selected block and dummy block of FIG. 3. Referring to FIG. 4, during a program operation of memory cells of the selected block Sel_BLK, a turn-on voltage may be applied to at least one of the string selection lines SSL1 to SSLk of the dummy block Dummy_BLK.

Cell strings NS11, NS12, and NS13 included in the selected block Sel_BLK may be selected by the string selection line SSL11. The cell strings NS11, NS12, and NS13 represent only some of the many cell strings of the selected block Sel_BLK. Accordingly, the operations of the cell strings NS11, NS12, and NS13 may represent the operations of all cell strings included in the selected block Sel_BLK.

One cell string NS13 of the selected block Sel_BLK may include a string selection transistor SST connected to the string selection line SSL11, and memory cells MC10 to MC16 connected to the word lines WL<0> to WL<6>, a ground selection transistor GST connected to the ground selection line GSL. The number of word lines and the number of selection lines (e.g., the string selection lines SSL, and the ground selection line GSL) that make up one cell string are simply expressed for convenience of explanation, but it is well understood that in reality, more word lines and selection lines may be included. All of the multiple cell strings included in the selected block Sel_BLK will have the same structure as the cell string NS13.

Cell strings NS21, NS22, NS23, NS31, NS32, NS33, NS41, NS42, and NS43 included in the dummy block Dummy_BLK can be selected by a plurality of string selection lines (e.g., string selection lines SSL1, SSL2, . . . , SSLk). The operation or structure of the cell strings NS21, NS22, NS23, NS31, NS32, NS33, NS41, NS42, and NS43 included in the dummy block Dummy_BLK are substantially the same as the cell string NS13 of the selected block Sel_BLK. For example, the cell string NS23 may include a string selection transistor SST21 connected to the string selection line SSL1, memory cells MC20 to MC26 connected to the word lines WL<0> to WL<6> respectively, and a ground selection transistor GST21 connected to the ground selection line GSL1. The number of word lines and the number of selection lines (e.g., string selection lines SSL, and gthe round selection line GSL) that make up one cell string are simply expressed for convenience of explanation, but it is well understood that in reality, more word lines and selection lines may be included.

When the program for the memory cells of one word line starts in the selected block Sel_BLK, setup for the bit lines BL0 to BL2 is performed in the first program loop. The bit lines BL0 to BL2 are shared by the selected block Sel_BLK and the dummy block Dummy_BLK, so they are controlled identically regardless of the memory block. Accordingly, each of the bit lines BL0 to BL2 is charged with the program bit line voltage (e.g., 0V) or the inhibit bit line voltage (e.g., VDD).

Once bit line setup is completed, the program for the selected memory cells is executed. At this time, the bit lines BL0 to BL2 are blocked from the sensing node of the page buffer. And the row decoder 1200 (see FIG. 1) applies the program voltage Vpgm to the word lines WL<0> to WL<6> of the selected block Sel_BLK. In addition, the row decoder 1200 applies a turn-on voltage to a preset number of string selection lines (e.g., string selection lines SSL1 to SSLk) in the dummy block Dummy_BLK. And the row decoder 1200 applies 0V or the dummy word line voltage VDWL to the word lines WL<0> to WL<6> of the dummy block Dummy_BLK. However, since bit line forcing does not need to be applied in the first program loop, the bit line remains blocked from the sensing node during the program execution section. On the other hand, in the second or higher program loop, a bit line forcing voltage to prevent over programming will be applied to the corresponding bit line.

In the second program loop, setup for the bit lines BL0 to BL2 is also performed. In the first loop, each of the bit lines BL0 to BL2 is charged with the program bit line voltage (e.g., 0V) or the inhibit bit line voltage (e.g., VDD). And in the second program loop, the number of string selection lines SSLs selected in the dummy block Dummy_BLK can be reduced. That is, a turn-on voltage may be applied only to the string selection lines SSL1 and SSL2 among the string selection lines of the dummy block Dummy_BLK, and an off voltage may be applied to the remaining string selection lines. In this state, the program voltage Vpgm and the pass voltage Vpass are applied to the word lines WL<0> to WL<6> of the selected block Sel_BLK. According to the number of loops, the program voltage Vpgm will increase in an incremental step pulse programming (ISPP) manner. And 0V or the dummy word line voltage VDWL will be applied to the word lines WL<0> to WL<6> of the dummy block Dummy_BLK.

The reason why the number of string selection lines SSLs selected in the dummy block Dummy_BLK decreases as the number of program loops increases is as follows. As the number of program loops increases, the threshold voltage of memory cells increases. Additionally, for memory cells that have been programmed in a target program state, an inhibit bit line voltage must be provided to the bit line, and bit line forcing will be applied to improve cell distribution. Therefore, as the number of loops increases, the required bit line capacitance relatively decreases. The change in bit line capacitance required according to the number of loops can be achieved by reducing the number of string selection lines SSLs selected in the dummy block Dummy_BLK.

According to the above, it has been explained that the required bit line capacitance can be compensated through selection of the string selection line SSL in the dummy block Dummy_BLK of embodiments of the present disclosure during program operation. In addition, by varying the number of string selection lines SSL in the selected dummy block Dummy_BLK, the required capacitance that changes as the number of program loops increases can be met. Therefore, the non-volatile memory device 1000 according to embodiments of the present disclosure solves problems of reduced program efficiency and program performance due to the length of the bit line.

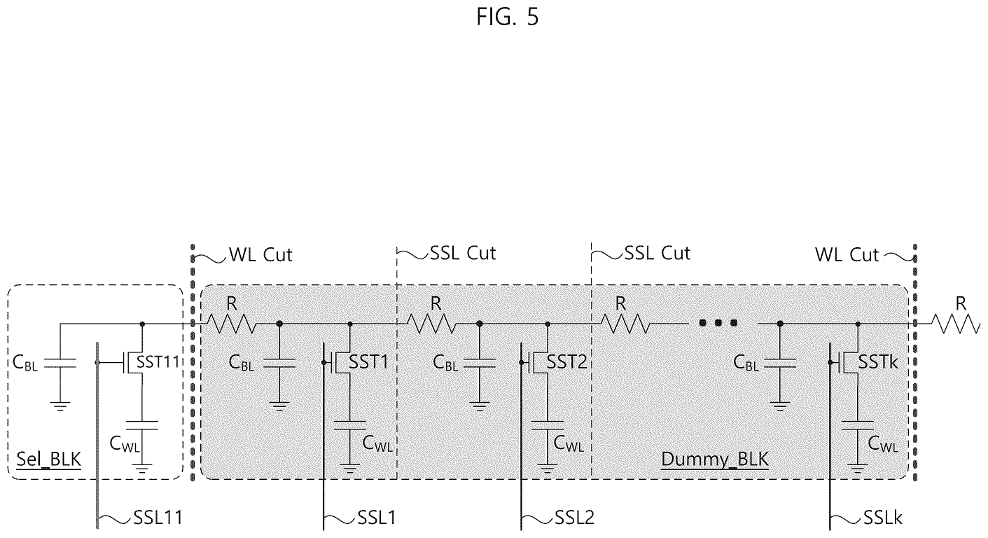

FIG. 5 is a circuit diagram illustrating a change in bit line capacitance of a dummy block Dummy_BLK provided through control of a string selection line. Referring to FIG. 5, the bit lines and cell strings of each of the selected block Sel_BLK and the dummy block Dummy_BLK can be modeled as bit line capacitance C_{BL}, bit line resistance R, string selection transistor SST, and word line capacitance C_{WL}.

The bit line BL of the selected block Sel_BLK may include the bit line capacitance C_{BL}, which is the inherent capacitance of the metal line itself. And when the turn- on voltage is applied to the string selection line SSL11, the string selection transistor SST11 is turned on, and the word line capacitance C_{WL} provided between the channel of the cell strings and the word line is added in parallel. However, as the length of the bit line decreases, the capacitance sum (C_{BL}+C_{WL}) of the selected block Sel_BLK may not be sufficient to prevent floating. At this time, when the turn-on voltage is applied to the string selection lines (e.g., string selection lines SSL1, SSL2, . . . , SSLk) of the dummy block Dummy_BLK, additional capacitance ‘k×(C_{BL}+C_{WL})’ may be provided. In addition, as the number of program loops increases, the reduction in required capacitance can be met by reducing the number of selections of the string selection lines (e.g., string selection lines SSL1, SSL2, . . . , SSLk) of the dummy block Dummy_BLK.

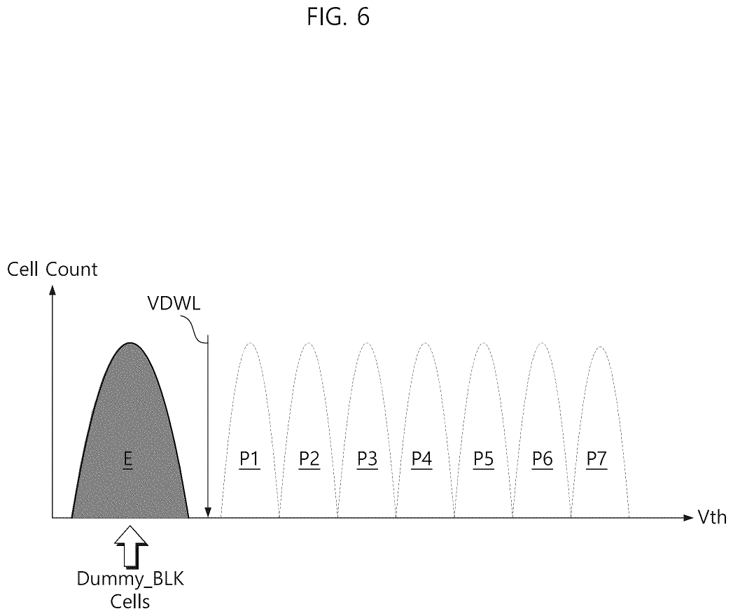

FIG. 6 is a diagram illustrating the program state of memory cells of a dummy block Dummy_BLK. Referring to FIG. 6, memory cells of the dummy block Dummy_BLK may be programmed to an erased state or a settable minimum threshold voltage level to maximize capacitance between the word line and the channel.

The nonvolatile memory device 1000 may perform a program for a dummy block Dummy_BLK during mass production or initialization. For example, when the dummy block Dummy_BLK is composed of triple level cell (TLC), the memory cells can be programmed at least one to an erase state E and seven program states P1, P2, P3, P4, P5, P6, P7. In this case, all memory cells of the dummy block Dummy_BLK of embodiments of the present disclosure may be programmed to the erase state E.

During a program operation of the selected block Sel_BLK, the dummy word line voltage VDWL may be provided to the word lines of the dummy block Dummy_BLK. The dummy word line voltage VDWL corresponds to a word line voltage that can ensure that all memory cells constituting the cell strings of the dummy block Dummy_BLK are turned off. In this case, the memory cells of the cell string selected in the dummy block Dummy_BLK are maintained in an off state by the dummy word line voltage VDWL. In this program state, word line capacitance C_{WL} can be guaranteed between the cell string channel and word line.

However, the program state of the memory cells of the dummy block Dummy_BLK is not limited to the above description. Memory cells of the dummy block Dummy_BLK may be programmed to the program state P1. In this case, the dummy word line voltage VDWL must be provided at a level higher than the program state P1. The dummy word line voltage VDWL only needs to be provided as a value to keep the memory cells of the dummy block Dummy_BLK in a turn-off state.

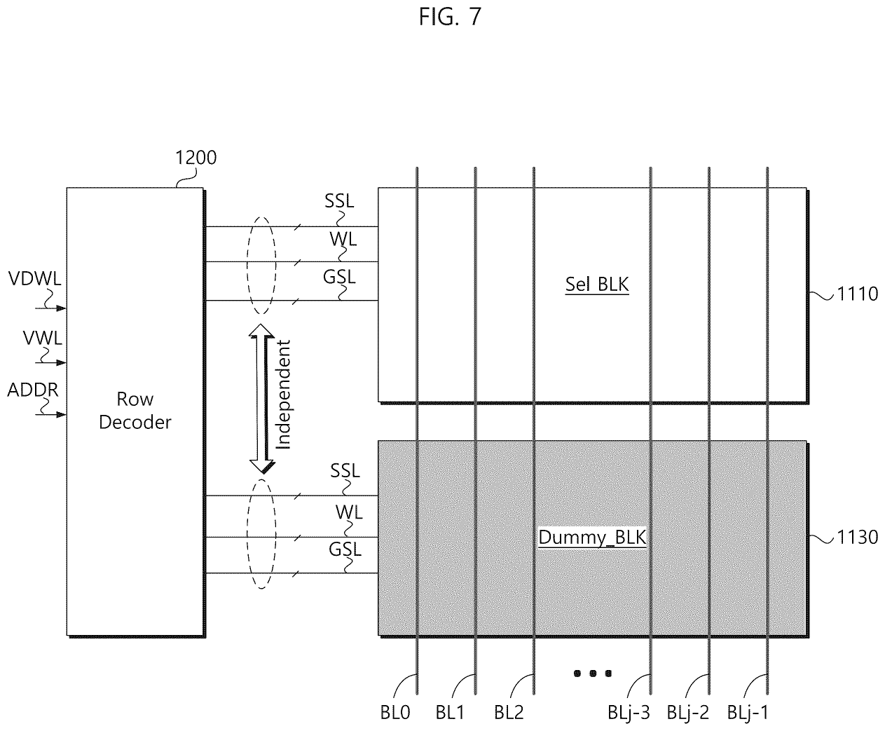

FIG. 7 is a block diagram showing the function of the row decoder of embodiments of the present disclosure. Referring to FIG. 7, the row decoder 1200 provides voltages (e.g., a word line voltage VWL and a dummy word line voltage VDWL) provided according to the address ADDR to the selected block Sel_BLK and the dummy block Dummy_BLK during program operation, and controls string selection lines SSL of the dummy block Dummy_BLK. At this time, the bit lines BL0 to BLj-1 are shared by the selected block Sel_BLK and the dummy block Dummy_BLK, so they are collectively controlled by the page buffer circuit 1300 (see FIG. 1).

The row decoder 1200 disables control of the dummy block Dummy_BLK during non-program operations such as read operations or erase operations. In other words, in operations other than programming, the row decoder 1200 blocks the supply of signals or voltages supplied to the string selection line SSL, ground selection line GSL, and word line WL of the dummy block Dummy_BLK. On the other hand, when the program operation starts, the row decoder 1200 activates control of the string selection line SSL, ground selection line GSL, and word line WL of the dummy block Dummy_BLK in synchronization with the string selection signal, ground selection signal, and word line voltage Vpgm and Vpass supplied to the selected block Sel_BLK.

When the program operation begins, the row decoder 1200 applies a turn-on voltage to the string selection line SSL, and the program voltage Vpgm and pass voltage Vpass to the word line WL of the selected block Sel_BLK. At the same time, the row decoder 1200 applies a turn-on voltage to the string selection line SSL and a dummy word line voltage VDWL to the word line WL of the dummy block Dummy_BLK. At this time, in the first program loop, the row decoder 1200 may select all string selection lines SSL of the dummy block Dummy_BLK to supply the turn-on voltage.

After the first program loop is completed, in the subsequent program loop, the row decoder 1200 applies the turn-on voltage to the string selection line SSL, an increased program voltage Vpgm and the pass voltage Vpass to the word lines WLs of the selected block Sel_BLK. Then, the row decoder 1200 applies the turn-on voltage to the reduced string selection lines SSL and a dummy word line voltage VDWL to the word lines WLs of the dummy block Dummy_BLK (see FIGS. 8-9). That is, whenever the number of loops increases after the second program loop, the row decoder 1200 may gradually decrease the number of string selection lines SSL to which the turn-on voltage is applied in the dummy block Dummy_BLK.

As described above, according to the dummy block Dummy_BLK of embodiments of the present disclosure, the bit line capacitance can be compensated through control of the string selection line SSL during the program operation of the selected block Sel_BLK. Accordingly, the nonvolatile memory device 1000 of embodiments of the present disclosure can prevent a decrease in program efficiency and performance caused by a reduction in the length of the bit line.

FIG. 8 and FIG. 9 are timing diagrams showing the control method for each operation mode of the cell strings of a dummy block Dummy_BLK of embodiments of the present disclosure. FIG. 8 shows a method of controlling the dummy block Dummy_BLK during a program operation in which bit line capacitance compensation is unnecessary, that is, a default operation. The default operation may be applied after a certain number of program loops or after the program in the target program state is completed.

Referring to FIG. 8, the adding function of the bit line capacitance of the dummy block Dummy_BLK is disabled, and only the program for the selected block Sel_BLK occurs. To this end, in the bit line setup section BL_Setup, the program bit line BL_p of the selected block Sel_BLK is set to 0V, and the inhibit bit line BL_inh is set to the inhibit bit line voltage (e.g., 2V). In this state, a turn-on voltage is temporarily applied to the selected string selection line SSL_sel, and a turn-on voltage is temporarily applied to the unselected string selection line SSL_unsel, but after then 0V is provided. The ground selection line GSL also maintains the ground level after the turn-on voltage is temporarily provided until program execution. In the program execution section PGM_EXE, the program voltage Vpgm will be provided to the selected word line WL_sel and the pass voltage Vpass will be provided to the unselected word line WL_unsel.

The default operating mode is with bit line capacitance addition disabled. Accordingly, all string selection lines SSL_all and word lines WL_all of the dummy block Dummy_BLK are maintained in a floating state during the bit line setup section BL_Setup and the program execution section PGM_EXE. The default operation mode can be used in situations where adding bit line capacitance using a dummy block Dummy_BLK is unnecessary.

FIG. 9 shows the control method of the dummy block Dummy_BLK during program operation that requires bit line capacitance compensation, divided into an initial program loop and subsequent program loops. Referring to FIG. 9, the number of string selection lines SSL selected in the dummy block Dummy_BLK in the first program loop may be set to decrease as the number of loops increases.

When the program operation of the selected block Sel_BLK requiring addition of bit line capacitance begins, the bit line capacitance addition function of the dummy block Dummy_BLK is activated. The program operation of the selected block Sel_BLK comprises or consists of a plurality of loops. To describe aspects of embodiments of the present disclosure, the first loop and the subsequent loops will be separately described below.

The first loop can be divided into a bit line setup section BL_Setup and a program execution section PGM_EXE. In the bit line setup section BL_Setup, the program bit line BL_p of the selected block Sel_BLK is set to the program bit line voltage (e.g., 0V), and the inhibit bit line BL_inh is set to the inhibit bit line voltage (e.g., 2V). In this state, the turn-on voltage is temporarily applied to the selected string selection line SSL_sel, and a turn-on voltage is temporarily applied to the unselected string selection line SSL_unsel, but after then 0V is provided. The ground selection line GSL also maintains the ground level after the turn-on voltage is temporarily provided until program execution. When the program execution section PGM_EXE begins, the program voltage Vpgm will be provided to the selected word line WL_sel and the pass voltage Vpass will be provided to the unselected word line WL_unsel.

In the first loop, the bit lines (e.g., the inhibit bit line BL_inh and the program bit line BL_p) of the dummy block Dummy_BLK are set equal to those of the select block Sel_BLK. However, the turn-on voltage is applied to the string selection lines SSL0, SSL1, and SSL2 of the dummy block Dummy_BLK. And 0V corresponding to the dummy word line voltage VDWL is applied to all word lines WL_all of the dummy block Dummy_BLK. In this case, the capacitance formed between the channels and word lines of all cell strings connected to the string selection lines SSL0, SSL1, and SSL2 may be added to the bit line capacitance. Accordingly, the maximum bit line capacitance can be added to the bit lines BL.

The second and subsequent loops (after the 1st loop) can also be divided into a bit line setup section BL_Setup and a program execution section PGM_EXE. In the bit line setup section BL_Setup, the program bit line BL_p of the selected block Sel_BLK is set to the program bit line voltage (e.g., 0V), and the inhibit bit line BL_inh is set to the inhibit bit line voltage (e.g., 2V). Then, a turn-on voltage is applied to the selected string selection line SSL_sel, and 0V is provided to the unselected string selection line SSL_unsel after the turn- on voltage is temporarily applied. The ground selection line GSL also maintains the ground level after the turn-on voltage is temporarily provided until program execution. When the program execution section PGM_EXE begins, the program voltage Vpgm will be provided to the selected word line WL_sel and the pass voltage Vpass will be provided to the unselected word line WL_unsel.

In the second and subsequent loops (after the 1st loop), the bit lines BL_inh and BL_p of the dummy block Dummy_BLK are set equal to those of the select block Sel_BLK. Unlike the first program loop, the turn-on voltage is applied only to the string selection line SSL0 among the string selection lines SSL0, SSL1, and SSL2 of the dummy block Dummy_BLK, and the remaining string selection lines SSL1 and SSL2 are maintained in a floating state. And 0V corresponding to the dummy word line voltage VDWL is applied to all word lines WL_all of the dummy block Dummy_BLK. In this case, only all cell strings connected to the string selection line SSL0 can contribute to increasing the bit line capacitance. Therefore, as the number of loops increases, the size of the added bit line capacitance may gradually decrease.

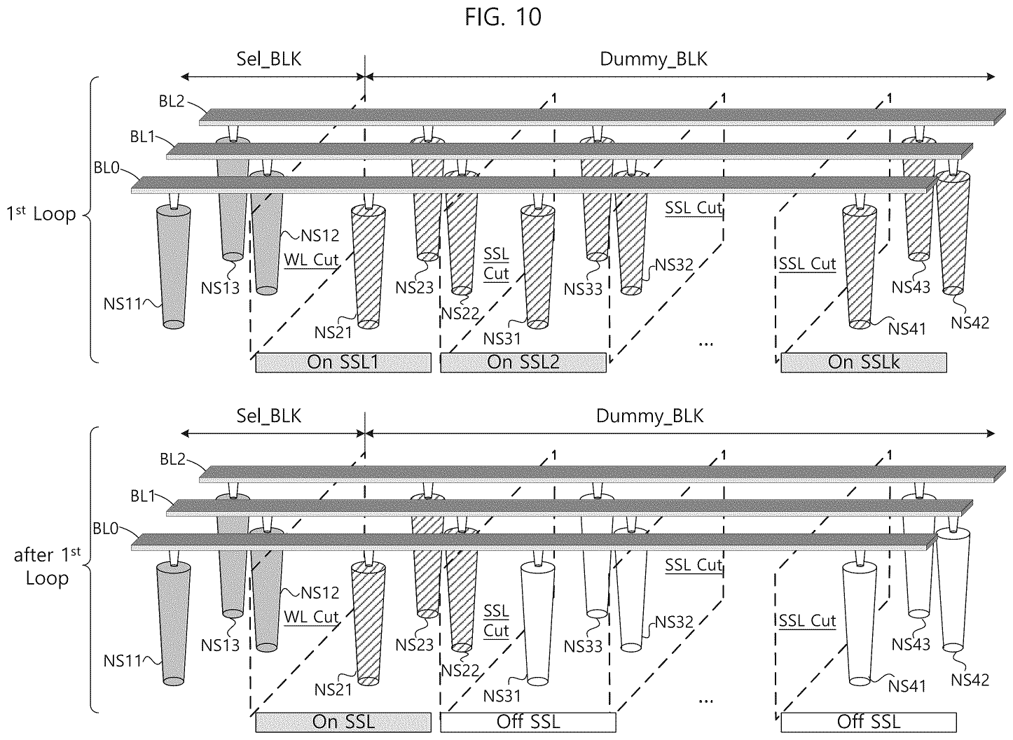

FIG. 10 is a diagram showing the number of strings of the dummy block Dummy_BLK contributing to the addition of bit line capacitance for each program loop under the conditions of FIG. 9. Referring to FIG. 10, the number of cell strings contributing to the bit line capacitance in the dummy block Dummy_BLK may vary depending on the number of program loops.

In the first loop, the program bit line BL_p of the selected block Sel_BLK is set to 0V, and the inhibit bit line BL_inh is set to the inhibit bit line voltage (e.g., 2V) (see FIG. 9). When the program execution section PGM_EXE begins, the program voltage Vpgm will be provided to the selected word line WL_sel of the selected block Sel_BLK, and the pass voltage Vpass will be provided to the unselected word line WL_unsel of the selected block Sel_BLK (see FIG. 9). On the other hand, a turn-on voltage is applied to the string selection lines (e.g., string selection lines SSL1, SSL2, . . . , SSLk) of the dummy block Dummy_BLK. And 0V corresponding to the dummy word line voltage VDWL is applied to all word lines WL_all of the dummy block Dummy_BLK (see FIG. 9). Then, the capacitance formed by all cell strings connected to the string selection lines (e.g., string selection lines SSL1, SSL2, . . . , SSLk) can be added to the bit line capacitance. Accordingly, the maximum bit line capacitance can be added to the bit lines BL0, BL1, and BL2.

In the second and subsequent loops (after the 1st loop), the program bit line BL_p of the selected block Sel_BLK is set to the program bit line voltage (e.g., 0V), and the inhibit bit line BL_inh of the selected block Sel_BLK is set to the inhibit bit line voltage (e.g., 2V) (see FIG. 9). When the program execution section PGM_EXE begins, the program voltage Vpgm will be provided to the selected word line WL_sel of the selected block Sel_BLK, and the pass voltage Vpass will be provided to the unselected word line WL_unsel of the selected block Sel_BLK (see FIG. 9). On the other hand, the turn-on voltage is applied to only one string selection line SSL1 among the string selection lines (e.g., string selection lines SSL1, SSL2, . . . , SSLk) of the dummy block Dummy_BLK. That is, the remaining string selection lines (e.g., string selection lines SSL2, . . . , SSLk) of the dummy block Dummy_BLK cannot be connected to the bit line. Accordingly, these remaining string selection lines (e.g., string selection lines SSL2, . . . , SSLk) do not contribute to the capacitance of the bit line. And in the program execution section PGM_EXE, 0V corresponding to the dummy word line voltage VDWL is applied to all word lines WL_all of the dummy block Dummy_BLK (see FIG. 9). Then, only cell strings connected to the string selection line SSL1 can contribute to the bit line capacitance. Accordingly, a capacitance reduced from the bit line capacitance provided by the dummy block Dummy_BLK in the first program loop is added to the bit lines (e.g., bit lines BL0, BL1, and BL2).

In the above, an example was described in which the number of string selection lines SSL selected in the dummy block Dummy_BLK is reduced as the number of loops increases. In other words, it was explained that the number of cell strings of the dummy block Dummy_BLK, which contributes to increasing the bit line capacitance, can be varied depending on the number of program loops. Accordingly, as the number of loops increases, the size of the bit line capacitance compensated may gradually decrease. Additionally, it will be understood that addition of bit line capacitance by a dummy block Dummy_BLK may be stopped after a specific program loop.

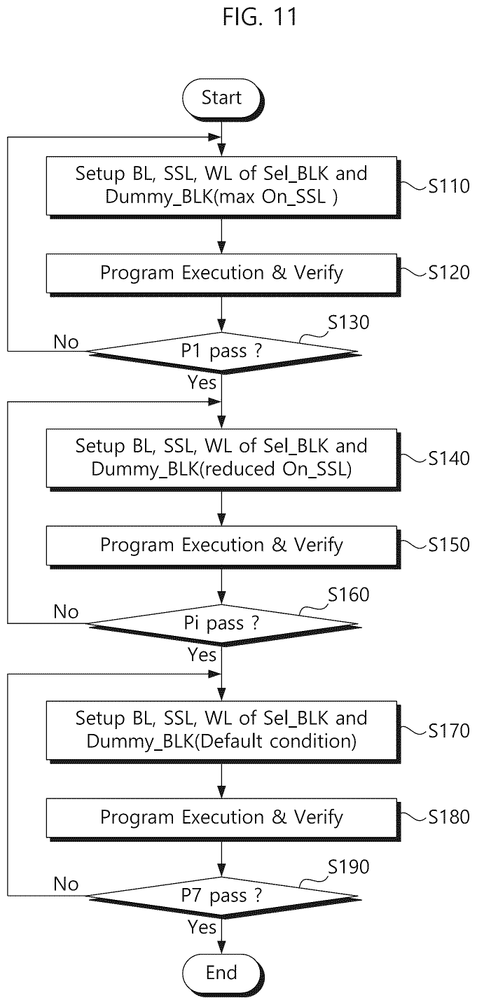

FIG. 11 is a flowchart showing a programming method according to an embodiment of the present disclosure. Referring to FIG. 11, the nonvolatile memory device 1000 of embodiments of the present disclosure can improve program performance by adjusting the bit line capacitance required during program operation according to the number of cell strings selected in the dummy block Dummy_BLK.

In operation S110, the first loop (the 1st loop) for programming the selected block Sel_BLK begins. For programming the selected block Sel_BLK, the program bit line BL_p is set to the program bit line voltage (e.g., 0V), and the inhibit bit line BL_inh is set to the inhibit bit line voltage (e.g., 2V) (see FIG. 9). And the dummy block Dummy_BLK will be set up so that the turn-on voltage is applied to the maximum number of string selection lines. In this state, a voltage (e.g., 0V) corresponding to the dummy word line voltage VDWL is applied to all word lines WL_all of the dummy block Dummy_BLK.

In operation S120, the program execution section PGM_EXE of the first loop (1st loop) begins. At this time, the program voltage Vpgm will be provided to the selected word line WL_sel of the selected block Sel_BLK, and the pass voltage Vpass will be provided to the unselected word line WL_unsel of the selected block Sel_BLK. Then, a turn- on voltage is applied to the maximum number of string selection lines of the dummy block Dummy_BLK. And the dummy word line voltage VDWL is maintained on all word lines WL_all of the dummy block Dummy_BLK. Then, the bit line capacitance can be increased by all cell strings connected to the string selection lines to which the turn-on voltage is applied. Due to the increased bit line capacitance, boosting of the floating bit lines may be blocked even if the program voltage Vpgm or the pass voltage Vpass is applied to the selected block Sel_BLK. Therefore, a decrease in program efficiency may be prevented.

In operation S130, it is detected whether the lowest program state (e.g., state P1) of the memory cells of the selected block Sel_BLK is passed through the progress of the first loop of the program operation. If the memory cells are not programmed to the lowest program state (P1) through the program operation in operations S110 to S120 (“No” direction), the procedure returns to operation S110 and reprogramming is performed under the setup conditions of the previous loop. On the other hand, if the memory cells are all programmed to the lowest program state (state P1) (“Yes” direction), the procedure moves to operation S140.

In operation S140, the second loop after the first loop for programming the selected block Sel_BLK begins. For programming of the selected block Sel_BLK, the program bit line BL_p is set to 0V and the inhibit bit line BL_inh is set to the inhibit bit line voltage (e.g., 2V). And in the dummy block Dummy_BLK, a reduced number of string selection lines are selected. And a turn-on voltage will be set to be applied to the selected string selection lines. In this state, a voltage (e.g., 0V) corresponding to the dummy word line voltage VDWL is applied to all word lines WL_all of the dummy block Dummy_BLK.

In operation S150, the program execution section PGM_EXE begins. At this time, the program voltage Vpgm will be provided to the selected word line WL_sel of the selected block Sel_BLK, and the pass voltage Vpass will be provided to the unselected word line WL_unsel of the selected block Sel_BLK. Then, the turn-on voltage is applied to the selected string selection lines of the dummy block Dummy_BLK. And the dummy word line voltage VDWL is maintained on all word lines WL_all of the dummy block Dummy_BLK. Then, the bit line capacitance can be increased by all cell strings connected to the string selection lines to which the turn-on voltage is applied. Even if the program voltage Vpgm or the pass voltage Vpass is applied to the selected block Sel_BLK due to the increased bit line capacitance, boosting of the floating bit lines may be blocked. Therefore, a decrease in program efficiency can be prevented.

In operation S160, it is detected whether the memory cells of the selected block Sel_BLK have been programmed to the target program state (state Pi) by program execution. If the memory cells are not programmed to the target program state (state Pi) through the program operation in operations S140 to S150 (“No” direction), the procedure returns to operation S140 and reprogramming is performed under the setup conditions of the previous loop. On the other hand, if the memory cells are all programmed to the target program state (state Pi) (“Yes” direction), the procedure moves to operation S170. Here, the target program state (state Pi) may be, for example, any one of the program states (e.g., states P2, P3, P4, P5, and P6) in FIG. 6.

At operation S170, a program loop under default operating conditions for the program of the selected block Sel_BLK begins. For programming the selected block Sel_BLK, the program bit line BL_p is set to the program bit line voltage (e.g., 0V), and the inhibit bit line BL_inh is set to the inhibit bit line voltage (e.g., 2V). On the other hand, according to the default operating conditions, all selection lines (e.g., all string selection SSL_all and ground selection line GSL) and all word lines WL_all of the dummy block Dummy_BLK are set to a floating state as shown in FIG. 8.

At operation S180, the program execution section PGM_EXE begins. At this time, the program voltage Vpgm will be provided to the selected word line WL_sel of the selected block Sel_BLK, and the pass voltage Vpass will be provided to the unselected word line WL_unsel of the selected block Sel_BLK. And all selection lines (e.g., all string selection SSL_all and ground selection line GSL) and all word lines WL_all of the dummy block Dummy_BLK will remain in the floating state. Accordingly, there is almost no capacitance added to the bit lines by the dummy block Dummy_BLK.

In operation S190, it is detected whether the memory cells of the selected block Sel_BLK have been programmed to the highest program state (e.g., state P7) by program execution. If the memory cells are not programmed to the highest program state (e.g., state P7) through the program operation in operations S170 to S180 (“No” direction), the procedure will return to operation S170 and reprogramming will be performed under default operating conditions. On the other hand, when all memory cells are programmed to the highest program state (e.g., state P7) (“Yes” direction), all program operations for the selected block Sel_BLK are terminated.

According to the programming method using the dummy block Dummy_BLK of embodiments of the present disclosure, the bit line capacitance can be compensated through the dummy block Dummy_BLK during the program operation of the selected block Sel_BLK. Accordingly, the nonvolatile memory device 1000 of embodiments of the present disclosure can prevent degradation of program efficiency and performance caused by reduction in the length of the bit line.

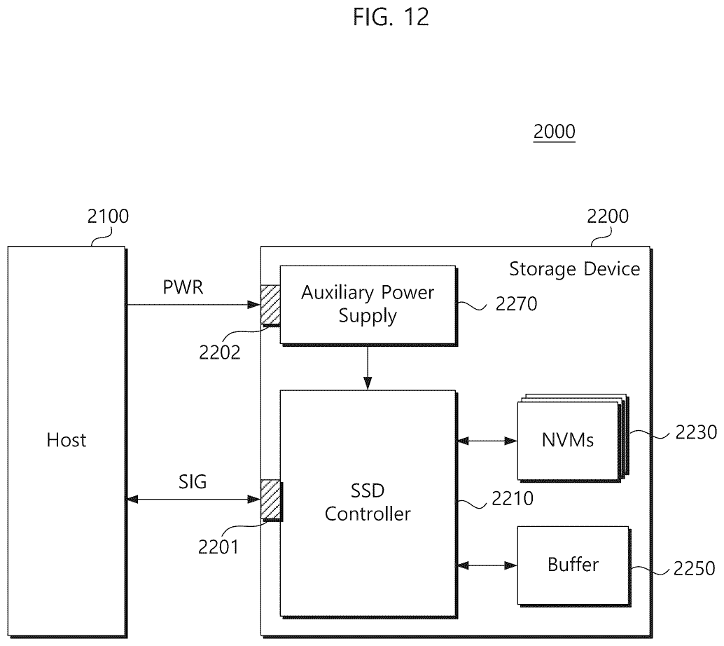

FIG. 12 is a block diagram showing a storage system including the non- volatile memory device of embodiments of the present disclosure. Referring to FIG. 12, a storage system 2000 includes a host 2100 and a storage device 2200 implemented as a solid state drive. In an example embodiment, the storage device 2200 may include a plurality of nonvolatile memory devices 2230, which may be a plurality of the nonvolatile memory devices 1000 described with reference to FIGS. 1 to 11.

The storage device 2200 exchanges a signal SIG with the host 2100 through the signal connector 2201 and receives power PWR through the power connector 2202. The storage devices 2200 may include a solid state drive (SSD) controller 2210, a plurality of non-volatile memory devices 2230, a buffer memory 2250, and an auxiliary power supply 2270.

The SSD controller 2210 may control a plurality of non-volatile memory devices 2230 in response to a signal SIG received from the host 2100. The plurality of non- volatile memory devices 2230 may operate under the control of the SSD controller 2210. The auxiliary power supply 2270 is connected to the host 2100 through the power connector 2202. The auxiliary power supply 2270 can receive power PWR from the host 2100 and charge it. The auxiliary power supply 2270 may provide power to the storage device 2200 when power supply from the host 2100 is not smooth. The buffer memory 2250 may be used as a buffer memory of the storage device 2200.

In an example embodiment, each of the plurality of non-volatile memory devices 2230 may include a dummy block Dummy_BLK used to compensate for bit line capacitance during a program operation. During program operation, the bit line capacitance of the selected memory block can be optimized by varying the number of string selection lines SSL to which the turn-on voltage is applied in the dummy block Dummy_BLK. Therefore, the problems of reduced program efficiency and program performance due to the length of the bit line can be solved through the use of a plurality of non-volatile memory devices 2230.

Non-limiting example embodiments of the present disclosure have been described above with reference to the drawings. Embodiments of the present disclosure can also be implemented in other specific forms that are included in the scope of the present disclosure. In addition, the present disclosure also include techniques that can be easily modified and implemented using the embodiments. Therefore, the scope of the present disclosure is not be limited to the above-described example embodiments.

What is claimed is:

1. A non-volatile memory device, comprising:
a first memory block connected to bit lines;
a second memory block connected to the bit lines and comprising:
string selection lines;
word lines; and
cell strings connected to the string selection lines and the word lines;
a row decoder configured to provide a turn-on voltage to at least one of the string selection lines of the second memory block during a program operation of the first memory block; and
a page buffer configured to perform program or inhibit settings for the bit lines during the program operation.

2. The non-volatile memory device of claim 1, wherein the row decoder is further configured to provide a turn-off voltage to the word lines of the second memory block that causes memory cells of the second memory block to be set to a turn-off state during the program operation of the first memory block.

3. The non-volatile memory device of claim 2, wherein the memory cells of the second memory block are programmed to maintain the turn-off state based on the turn-off voltage.

4. The non-volatile memory device of claim 3, wherein the memory cells of the second memory block are maintained in an erased state.

5. The non-volatile memory device of claim 1, wherein the row decoder is further configured to vary a number of the string selection lines to which the turn-on voltage is applied in the second memory block according to a number of program loops during the program operation of the first memory block.

6. The non-volatile memory device of claim 5, wherein the row decoder is further configured to reduce the number of the string selection lines to which the turn-on voltage is applied as the number of program loops increases.

7. The non-volatile memory device of claim 6, wherein the row decoder is further configured to apply a turn-off voltage to the string selection lines of the second memory block after memory cells of the first memory block are programmed to a target program state.

8. The non-volatile memory device of claim 1, further comprising:
a control logic circuit configured to control the page buffer and the row decoder to set the bit lines, the string selection lines, and the word lines of the second memory block according to a number of program loops during the program operation of the first memory block.

9. A method of programming a non-volatile memory device, the method comprising:
setting bit lines of a first memory block that includes target memory cells to be programmed;
setting at least one string selection line of a second memory block connected to the bit lines to a turn-on voltage; and
applying a program voltage to word lines of the target memory cells of the first memory block.

10. The method of claim 9, further comprising maintaining memory cells of the second memory block in a turn-off state by applying a turn-off voltage to word lines of the second memory block.

11. The method of claim 10, wherein the turn-off voltage is 0V.

12. The method of claim 11, further comprising:
programming the memory cells of the second memory block to an erased state.

13. The method of claim 9, wherein a number of the at least one string selection line that is set to the turn-on voltage is based on a number of program loops of the programming.

14. The method of claim 13, wherein the number of the at least one string selection line set to the turn-on voltage decreases as the number of program loops increases.

15. The method of claim 9, wherein a number of the at least one string selection line set to the turn-on voltage is based on a threshold voltage at which the target memory cells of the first memory block are programmed.

16. A non-volatile memory device, comprising:
a first memory block connected to at least one bit line; and
a second memory block configured to connect at least one cell string to the at least one bit line in response to a turn-on voltage applied to string selection lines during a program operation of the first memory block.

17. The non-volatile memory device of claim 16, further comprising:
a row decoder configured to provide a program voltage or a pass voltage to word lines of the first memory block, and a turn-off voltage to a word line of the second memory block that causes memory cells included in the at least one cell string to maintain in a turn-off state.

18. The non-volatile memory device of claim 17, wherein the row decoder is further configured to vary a number of the string selection lines to which the turn-on voltage is applied in the second memory block according to a number of program loops during the program operation.

19. The non-volatile memory device of claim 18, wherein the row decoder is further configured to reduce the number of the string selection lines to which the turn-on voltage is applied as the number of program loops increases.

20. The non-volatile memory device of claim 19, wherein the memory cells of the second memory block are in an erase state, and the turn-off voltage is 0V.
